(19) United States
(12) Patent Application Publication
(10) Pub. No.: US 2008/0035940 A1
(43) Pub. Date: Feb. 14, 2008

(54) Selective smile formation under transfer gate in a CMOS image sensor pixel

(76) Inventor: Satyadev H. Nagaraja, San Jose, CA (US)

Correspondence Address: BLAKELY SOKOLOFF TAYLOR & ZAFMAN LLP, 1279 Oakmead Parkway, Sunnyvale, CA, 94085-4040, US

(21) Appl. No.: 11/974,436

(22) Filed: Oct. 12, 2007

Related U.S. Application Data
(62) Division of application No. 11/112,289, filed on Apr. 22, 2005.

(51) Int. Cl. H01L 33/00; H01L 21/00

(52) U.S. Cl. 257/94; 438/38; 257/E33.001; 257/E21.001

(57) ABSTRACT

A pixel includes a photodiode and a transfer transistor. The transfer transistor is formed between the photodiode and a floating node and selectively operative to transfer a signal from the photodiode to the floating node. The transfer transistor has a bird's beak structure formed at the interface of its transfer gate and said floating node. Also included is a reset transistor for resetting the floating node to a voltage reference and an amplification transistor controlled by the floating node.

### TECHNICAL FIELD

The present invention relates to image sensors, and more particularly, to an image sensor that uses pixels having a transfer gate with an underlying asymmetric bird's beak smile.

### BACKGROUND

Image sensors have become ubiquitous. They are widely used in digital still cameras, cellular phones, security cameras, medical, automobile, and other applications. The technology used to manufacture image sensors, and in particular CMOS image sensors, has continued to advance at great pace. For example, the demands of higher resolution and lower power consumption have encouraged the further miniaturization and integration of the image sensor.

Possibly as a result of the greater miniaturization and integration of the image sensor, various issues for both CMOS and CCD image sensors have arisen. For example, image lag and leakage current are important issues that need to be improved upon. As greater integration takes place, leakage current from a floating diffusion (also known as floating node) may become problematic. Specifically, leakage current through the channel-LDD (lightly doped drain) junction may occur. Additionally, image lag due to insufficient transfer of signal from the photodiode, through the channel of the transfer transistor, to the floating node is also an issue.

These and other issues related to greater integration need to be addressed.

### BRIEF DESCRIPTION OF THE DRAWINGS

FIG. 1 is a cross-sectional view of a prior art four transistor (4T) pixel which shows in detail a photodiode formed in a substrate.

FIGS. 2-5 are cross-sectional views of a process for forming a photodiode and pixel in accordance with the present invention.

### DETAILED DESCRIPTION

In the following description, numerous specific details are provided in order to give a thorough understanding of embodiments of the invention. One skilled in the relevant art will recognize, however, that the invention may be practiced without one or more of the specific details, or with other methods, components, materials, etc. In other instances, well known structures, materials, or operations are not shown or described in order to avoid obscuring aspects of the invention.

References throughout the specification to “one embodiment” or “an embodiment” means that a particular feature, structure, or characteristic described in connection with the embodiment and included in at least one embodiment of the present invention. Thus, the appearances of the phrase “in one embodiment” or “in an embodiment” in various places throughout the specification are not necessarily all referring to the same embodiment. Furthermore, the particular features, structures, or characteristics may be combined in any suitable manner in one or more embodiments.

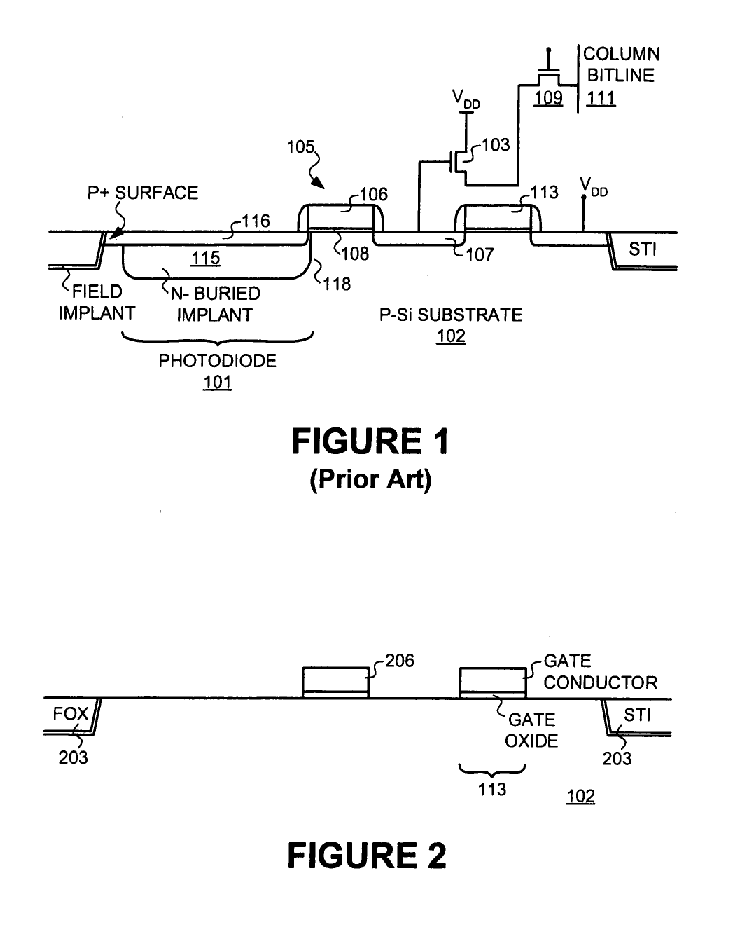

FIG. 1 shows a cross-sectional view of a prior art active pixel that uses four transistors. This is known in the art as a 4T active pixel. However, it can be appreciated that the photodiode design and process of the present invention can be used with any type of pixel design, including but not limited to 4T, 5T, 6T, and other designs. Further, the photodiode design of the present invention may also be used in connection with charge coupled device (CCD) imagers. The photodiode may also be a partially pinned photodiode.

A photodiode 101, outputs a signal that is used to modulate an amplification transistor 103. The amplification transistor 103 is also referred to as a source follower transistor. In this embodiment, the photodiode 101 can be either a pinned photodiode or a partially pinned photodiode. The photodiode 101 comprises a N⁻ layer 115 that is a buried implant. Additionally, in one embodiment, a shallow P⁺ pinning layer 116 is formed at the surface of the semiconductor substrate 102.

It should be noted that the semiconductor substrate 102 is a p-type silicon substrate, but in other embodiments may be an n-type silicon substrate. Further, various structures are formed atop of and into the silicon substrate 102. For example, the photodiode 101 and the floating node 107 are formed into the silicon substrate 102. These structures are said to be formed below the surface of the silicon substrate by the use of dopants. Similarly, field oxides or shallow trench isolation structures are also formed at and below the top surface (or simply surface) of the silicon substrate.

In contrast, other structures, such as the gate oxide 108, the transfer gate 106, the transfer transistor 105, and the reset transistor 113 are formed atop of the silicon substrate 102 and are said to be at or above the top surface of the silicon substrate.

A transfer transistor 105 is used to transfer the signal output by the photodiode 101 to a floating node 107 (N+ doped), which is adjacent to the gate of the transfer transistor 105. The transfer transistor 105 is controlled by a transfer gate 106. The transfer transistor 105 also has a gate oxide 108 underneath the transfer gate 106.

In operation, during an integration period (also referred to as an exposure or accumulation period), the photodiode 101 stores charge that is held in the N⁻ layer 115. After the integration period, the transfer transistor 105 is turned on to transfer the charge held in the N⁻ layer 115 of the photodiode 101 to the floating node 107. After the signal has been transferred to the floating node 107, the transfer transistor 105 is turned off again for the start of a subsequent integration period.

The signal on the floating node 107 is then used to modulate the amplification transistor 103. Finally, an address transistor 109 is used as a means to address the pixel and to selectively read out the signal onto a column bitline 111. After readout through the column bitline 111, a reset transistor 113 resets the floating node 107 to a reference voltage. In one embodiment, the reference voltage is V_{dd}. As seen in FIG. 1, the N⁻ layer 115 is linked to the transfer transistor 105 by a narrow neck region 118.

The present invention will now be described in connection with FIGS. 2-5. Turning to FIG. 2, a semiconductor substrate 102 is shown. In one embodiment, the semiconductor substrate 102 is a silicon substrate. A standard isolation 203, such as a LOCOS field oxide, or a shallow trench isolation (STI) defines an active area within the semiconductor substrate 102. In FIG. 2, a field oxide is shown at one boundary and a STI is shown at another boundary of the pixel. This is meant to be illustrative of two different types of isolations, and in many embodiments, the boundary around a pixel will either be completely STI or completely LOCOS field oxide or completely another variety of isolation. In one embodiment, the field oxide or shallow trench isolation is lined with a P-type field implant. The isolation 203 is used to electrically isolate an active area that will contain a pixel.

Still referring to FIG. 2, a transistor gate stack is deposited and etched to form a stack of gate oxide/polysilicon (conductor). In one embodiment, the transistor gate stack is formed by the deposition or growth of a relatively thin gate oxide layer using conventional semiconductor processing methods, such as thermal growth or chemical vapor deposition. Next, a conductive layer, such as a polysilicon layer, is deposited over the gate oxide layer. The polysilicon layer (when patterned, etched, and possibly doped) will serve as the gate of the various transistors such as the transfer transistor 105 or the reset transistor 113.

After deposition of these two layers, the stack is patterned and etched to leave the gate stack structures shown in FIG. 2. These two structures will eventually form the transfer gate 206 and the gate of the reset transistor 113.

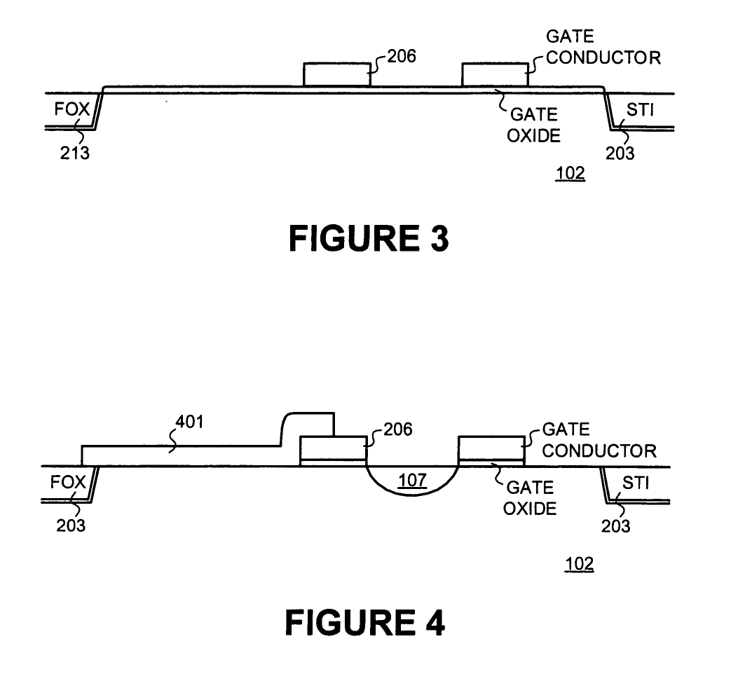

The present invention utilizes the selective formation of “smiles” (also referred to as a bird's beak) during a re-oxidation of the polysilicon transfer gate 206. As known by those skilled in the art, a bird's beak results from the lifting of a layer (such as polysilicon or nitride) due to an oxidation process. See www.sematech.org. This re-oxidation can occur and be implemented in several locations in the process flow. For example, turning to FIG. 3, in one alternative embodiment, the gate stacks are formed by only etching the polysilicon layer and not the underlying gate oxide layer. In this embodiment, the gate oxide layer is left on the surface of the semiconductor substrate 102.

Using either FIG. 3 or FIG. 2 as a starting point, a protective layer 401 (seen in FIG. 4) is deposited, patterned, and etched such that the protective layer 401 covers the interface between the transfer gate and the photodiode region. In one embodiment, the protective layer 401 is a nitride layer having a thickness of approximately 500 angstroms. However, it can be appreciated that other protective layers may also be used. One important consideration is that the interface between the transfer gate and the photodiode be protected from a subsequent re-oxidation step. While the protective layer 401 is shown extending to the field oxide 203, this is not absolutely necessary. Thus, FIG. 4 is merely illustrative of a single embodiment of the present invention.

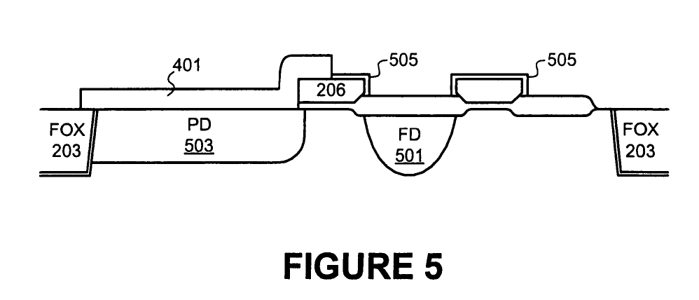

Next, turning to FIG. 5, a re-oxidation process is performed which will result in a thickening of the gate oxide near the floating diffusion 107 and transfer gate 206. In one embodiment, the re-oxidation is performed using a rapid thermal oxidation (RTO) process. This thickened gate oxide near the floating diffusion is beneficial as it reduces the leakage current through the channel-LDD junction. It prevents leakage of charge from the floating diffusion. However, near the photodiode interface with the transfer gate 206, there is no thickening of the gate oxide. This absence of a bird's beak at that location will enhance the electrical field. This increases the coupling between the N⁻ region of the photodiode and the channel under the transfer gate. This facilitates the speedy and efficient transfer of the accumulated signal in the N⁻ region of the photodiode to the floating node 501.

Thus, turning to FIG. 5, after the re-oxidation step, the oxide above the floating diffusion 501 is thickened causing a bird's beak structure to be formed at the interface between the floating diffusion 501 and the transfer gate 206. Because of the protective layer 401, there is no formation of a bird's beak structure at the photodiode 503 interface to the transfer gate 206. Note also that in one embodiment, there is also a bird's beak structure at the interface between the reset gate of the reset transistor and the floating node 501.

After the re-oxidation step, the protective layer 401 can be removed. Note that there is some ancillary oxide 505 formation on the side walls and the top of the transfer gate 206 in the reset gate. This ancillary oxide 505 may need to be removed to allow contact to the polysilicon gate material.

From the foregoing, it will be appreciated that specific embodiments of the invention have been described herein for purposes of illustration, but that various modifications may be made without deviating from the spirit and scope of the invention. Accordingly, the invention is not limited except as by the appended claims.

1. A method of forming an active pixel comprising:
forming a photodiode in an active area of a semiconductor substrate;
forming a transfer transistor between said photodiode and a floating node, said transfer transistor having a bird's beak structure formed at the interface of its transfer gate and said floating node; and
forming a reset transistor operative for resetting said floating node to a voltage reference.

2. The method of claim 1 wherein said transfer transistor does not have a bird's beak structure at the interface of its transfer gate and said photodiode.

3. The method of claim 1 wherein said reset transistor has a bird's beak structure at both sides of its reset gate.

4. The method of claim 1 wherein said bird's beak structure is formed using thermal re-oxidation.

5. A method for forming a pixel comprising:
forming an isolation in a semiconductor substrate to define an active area;
forming a gate oxide over said active area;
forming a polysilicon layer over said gate oxide;
patterning said polysilicon layer to form a transfer gate and a reset gate;
forming a photodiode in said semiconductor substrate and adjacent to said transfer gate;
forming a floating node between said transfer gate and said reset gate;
forming a protective layer over the interface of said transfer gate and said photodiode; and
performing a re-oxidation process to form a bird's beak structure at the interface of said transfer gate and said floating node.

6. The method of claim 5 further including removing said protective layer after said re-oxidation process.

7. The method of claim 6 wherein said protective layer is a nitride.

8. The method of claim 5 further wherein said re-oxidation process also forms a bird's beak structure at the interface of said reset gate and said floating node.

9.-12. (canceled)
